(19) United States
(12) Patent Application Publication
(10) Pub. No.: US 2010/0253183 A1
(43) Pub. Date: Oct. 7, 2010

(54) PIEZOELECTRIC FILM SENSOR

(75) Inventors: Mitsuhiro Ando, Aichi (JP); Eiji Fujioka, Aichi (JP); Shunsuke Kogure, Aichi (JP); Hitoshi Takayanagi, Aichi (JP); Nobuhiro Moriyama, Tokyo (JP); Ryuichi Sudo, Niigata (JP)

Correspondence Address: BUCHANAN, INGERSOLL & ROONEY PC, POST OFFICE BOX 1404, ALEXANDRIA, VA, 22313-1404, US

(73) Assignees: AISIN SEIKI KABUSHIKI KAISHA, Kariya-shi, Aichi (JP); KUREHA CORPORATION, CHUO-KU, TOKYO (JP)

(21) Appl. No.: 12/675,674

(22) PCT Filed: Aug. 8, 2008
(86) PCT No.: PCT/JP2008/064269

§ 371 Date: Feb. 26, 2010

(30) Foreign Application Priority Data
Aug. 28, 2007 (JP) 2007-221515

(51) Int. Cl. H01L 41/053; G01L 1/16; H01L 41/047

(52) U.S. Cl. 310/338; 310/345; 310/365

(57) ABSTRACT

A piezoelectric film sensor includes a substrate 1 having a signal electrode 2 and a ground electrode 3 formed on the surface thereof, the substrate being folded to cause the signal electrode 2 and the ground electrode 3 to be overlapped with each other in a plane view, a piezoelectric film 5 inserted between the signal electrode 2 and the ground electrode 3 formed on the substrate 1 and a bonding layer 6 for bonding the folded substrate 1 thereby to affix the signal electrode 2, the ground electrode 3 and the piezoelectric film 5 together.

### TECHNICAL FIELD

The present invention relates to a piezoelectric film sensor having a piezoelectric film.

### BACKGROUND ART

Conventionally, a piezoelectric sensor having a piezoelectric film formed of a polymer material, in particular, polyvinylidene fluoride (PVDF) is employed as a pressure sensor for determining presence/absence of a human, an animal, an object, etc. by detecting a load applied to an elastic support such as a bed, a mat, a sheet, etc. When the piezoelectric sensor is employed as such pressure sensor, in order to dispose the piezoelectric sensor precisely at the load detecting position in the support, the piezoelectric member is formed to suit its disposing shape relative to the support and then electrodes and wires are provided on its faces, thereby to complete the pressure sensor.

According to one known example of such piezoelectric sensor, silver paste is applied to both faces (sides) of a piezoelectric film, so as to form one side as a signal electrode and the other side as a ground electrode (see Patent Document 1 for example). With this piezoelectric sensor, on the signal electrode side of the piezoelectric film, there are laminated an insulating layer and a shield layer, and on the ground electrode side of the piezoelectric member, an insulating layer is laminated via bonding agent.

### Patent Document 1: Japanese Patent Application “Kokai” No. 10-332509

### DISCLOSURE OF THE INVENTION

However, with the piezoelectric sensor disclosed in Patent Document 1, as its manufacture involves laminating a plurality of layers such as the piezoelectric film, the electrode layers, the shield layer, the bonding layer, the insulating layers, the manufacturing steps and costs are so increased that the making it as a commercial product was not feasible. Further, a great amount of trouble and costs were required in precisely positioning terminal portions of the respective layers during the laminating process.

Moreover, in the case of the piezoelectric sensor disclosed in Patent Document 1, the electrodes are provided by directly applying an amount of silver paste on the faces of the piezoelectric film formed of polyvinylidene fluoride (PVDF). However, the heat resistance temperature (upper temperature limit) of PVDF is as low as 120° C. or lower. So, if the silver paste is to be dried at its normal drying temperature of 150° C. approximately, the piezoelectric property of PVDF can be deteriorated. For this reason, it is difficult to form electrodes in a stable manner in the PVDF per se. Furthermore, due to a difference of heat expansion ratio, exfoliation and/or wire break may occur. So, this involves a factor impairing reliability.

The present invention has been made in view of the above-described drawbacks and its object is to provide a piezoelectric sensor which allows easy simplification of its assembly process and which also has high reliability.

For accomplishing the above-noted object, according to a characterizing feature of a piezoelectric film sensor relating to the present invention, the piezoelectric sensor comprises:

a substrate having a signal electrode and a ground electrode formed on the surface thereof, the substrate being folded to cause the signal electrode and the ground electrode to be overlapped with each other in a plane view;

a piezoelectric film inserted between the signal electrode and the ground electrode formed on the substrate; and

a bonding layer for bonding the folded substrate thereby to affix the signal electrode, the ground electrode and the piezoelectric film together.

With the above construction, the substrate is folded so that the signal electrode and the ground electrode formed on one face thereof are overlapped in a plane view and the piezoelectric film is disposed in correspondence with the portion of this substrate where the two electrodes are overlapped with each other. With this, the piezoelectric film sensor can be manufactured simply by forming two electrodes on a single substrate in advance and then folding the substrate at the folding portion. Therefore, the manufacture process is simplified and the manufacture costs can be reduced.

According to a further characterizing feature of the piezoelectric film sensor relating to the present invention, terminals of both the signal electrode and the ground electrode are provided in a concentrated manner in at least one of a plurality of areas of the substrate sectioned from each other by the folding.

With the above-described construction, when the substrate is folded during the assembly process, a certain amount of positioning error is permitted for the signal electrode and the ground electrode. That is to say, in order to form terminals of the two electrodes in the piezoelectric film sensor, according to the above construction, these two terminals are formed in advance in at least one area of a plurality of areas that are sectioned from each other by the folding of the substrate. Therefore, in the course of folding of the substrate, no positioning error occurs between the terminals. For this reason, the assembly process of the piezoelectric film sensor can be simplified significantly and the manufacture costs can be reduced.

Further, according to a further characterizing feature of the piezoelectric film sensor relating to the present invention, the signal electrode and the ground electrode are formed on a same face of the substrate.

With the above-described construction, the formation of the electrodes can be completed only on one face of the substrate. Therefore, the step of forming the electrodes is simplified and the manufacture costs can be further reduced.

According to a still further characterizing feature of the piezoelectric film sensor relating to the present invention, on the back side of the face having the signal electrode formed thereon, a second ground electrode is formed.

With the above-described construction, both sides of the signal electrode can be sandwiched between two ground electrodes. As a result, noise from the outside can be shielded by the second ground electrode, thus being prevented from entering the signal electrode. Therefore, it is possible to provide a piezoelectric film sensor having high sensitivity. Moreover, as this construction requires only forming in advance the second ground electrode on the back side of the face having the signal electrode thereon and then folding the substrate, sensitivity enhancement and simplification of the assembly process of the piezoelectric film sensor can be realized at one time.

According to a still further characterizing feature of the piezoelectric film sensor relating to the present invention, the substrate is folded at least two portions thereof to cause the signal electrode to be sandwiched between the ground electrode in the plane view. In this, the “ground electrode” that sandwiches the signal electrode can be separate ground electrodes as a manner of course, but can also be a folded single ground electrode.

With the above-described construction, the signal electrode is shielded against external noise as being sandwiched by the ground electrode. Therefore, by the extremely simple assembly process of folding the substrate two times with not so high positional precision, a piezoelectric film sensor having high sensitivity can be manufactured.

According to a still further characterizing feature of the piezoelectric film sensor relating to the present invention, terminals of the signal electrode and the ground electrode are provided in a concentrated manner at the folded portion of the substrate.

With the above-described construction, the length of an electrode to be extended from a different area to the terminal provided at the folded portion can be short. Accordingly, the formation of electrodes can be carried out in an efficient manner.

Further, with the above-described construction, if a connector is connected to the portion where the terminals of the signal electrode and the ground electrode are present, this terminal connector fixes the folded portion of the substrate, thus functioning as a “clamp” for restricting a force in the direction tending to exfoliate or separate the folded substrate. With this, further simplification of the assembly process and further improvement of the reliability of the piezoelectric film sensor are made possible.

Incidentally, in the above-described constructions of the piezoelectric film sensor, preferably, the substrate includes a first substrate portion and a second substrate portion that are sectioned from each other by the folding of this substrate; and the signal electrode is provided in the first substrate portion and the ground electrode is provided in the second substrate portion.

Alternatively preferably, the substrate is folded at least at two portions so as to cause the signal electrode to be sandwiched by a ground electrode in the plane view;

the substrate includes a first substrate portion, a second substrate portion and a third substrate portion that are sectioned from each other by folding of the substrate;

the first substrate portion and the second substrate portion are sectioned from each other by a first folded portion and the second substrate portion and the third substrate portion are sectioned from each other by a second folded portion; and

the signal electrode is provided in the first substrate portion, the ground electrode is provided in the second substrate portion and the second ground electrode is provided in the third substrate portion.

With these arrangements, it is readily possible to realize the piezoelectric film sensor construction comprising:

a substrate having a signal electrode and a ground electrode formed on the surface thereof, the substrate being folded to cause the signal electrode and the ground electrode to be overlapped with each other in a plane view;

a piezoelectric film inserted between the signal electrode and the ground electrode formed on the substrate; and

a bonding layer for bonding the folded substrate thereby to affix the signal electrode, the ground electrode and the piezoelectric film together.

Still preferably, in the periphery of the two terminals of the signal electrode and the ground electrode provided in the concentrated manner, a cutout is formed, so that with the folding of the substrate, the two terminals are exposed to the outside.

With this arrangement, in the case of providing the terminals of the signal electrode and the ground electrode in a concentrated manner at the folded portion of the substrate, these terminals can be formed easily and appropriately.

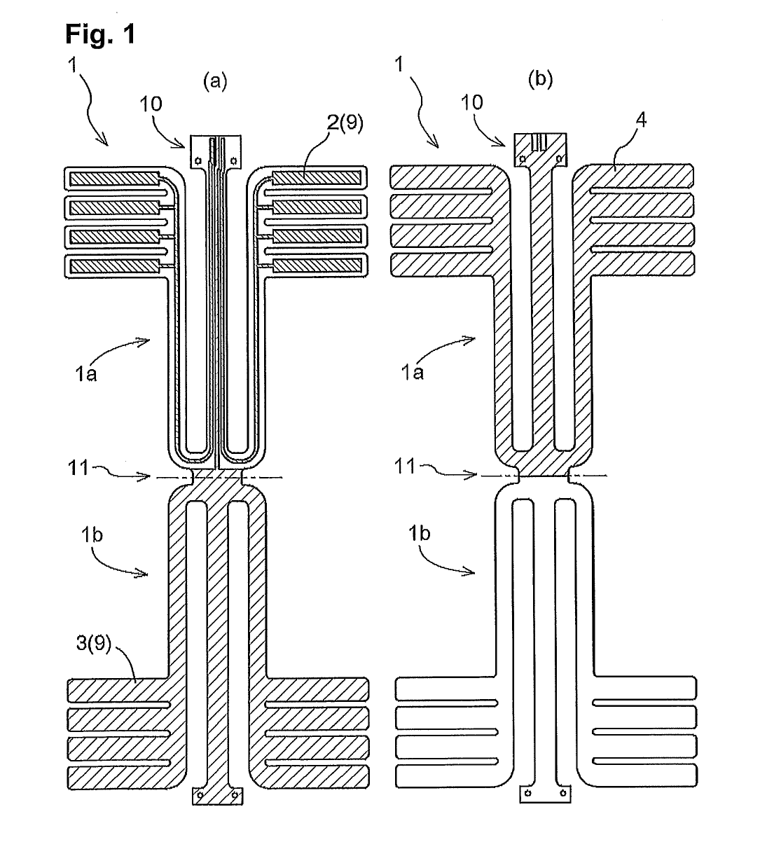

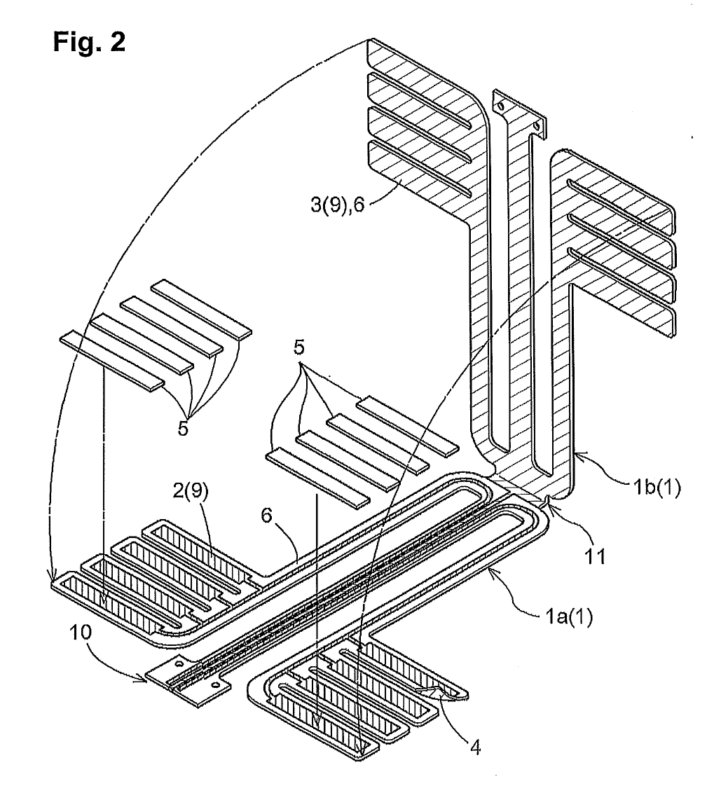

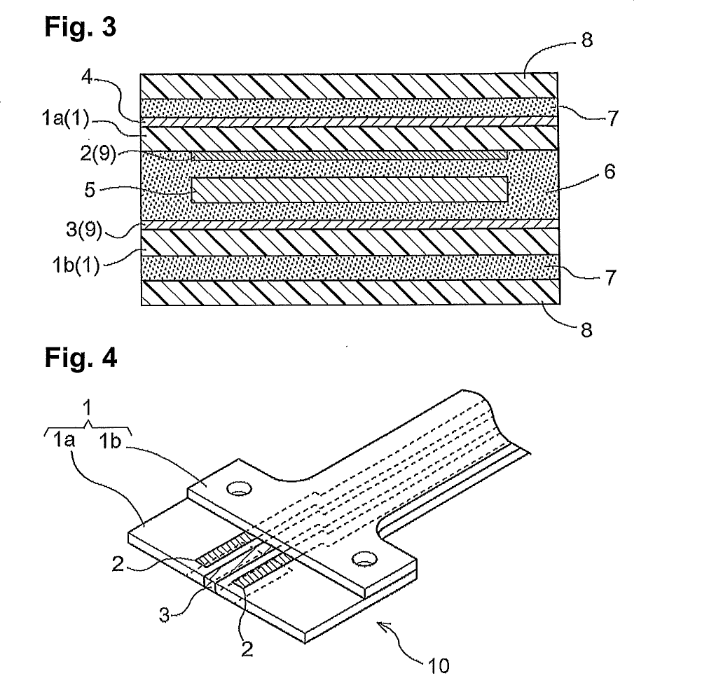

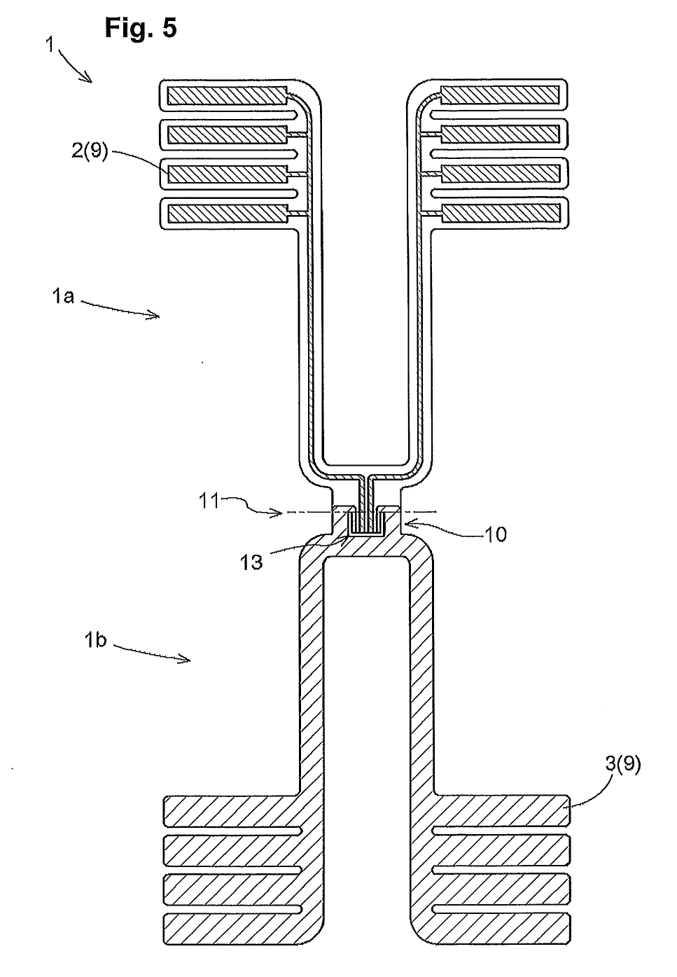

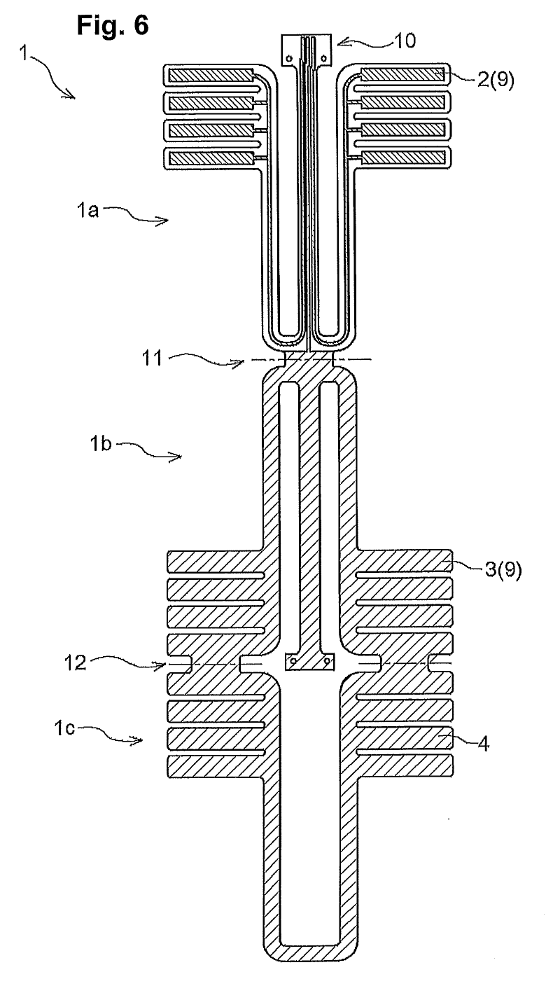

### BRIEF DESCRIPTION OF THE DRAWINGS

[FIG. 1] are developments in a plane view of a substrate having electrodes formed therein included in a piezoelectric film sensor relating to a first embodiment of the invention,

[FIG. 2] is a perspective view illustrating a manufacturing process of the piezoelectric film sensor relating to the first embodiment of the invention,

[FIG. 3] is a section view of a detecting portion of the piezoelectric film sensor relating to the first embodiment of the invention,

[FIG. 4] is a perspective view of a terminal of the piezoelectric film sensor relating to the first embodiment of the invention,

[FIG. 5] is a development in a plane view of a substrate having electrodes formed therein included in a piezoelectric film sensor relating to a second embodiment of the invention, and

[FIG. 6] is a development in a plane view of a substrate having electrodes formed therein included in a piezoelectric film sensor relating to a third embodiment of the invention.

### BEST MODE OF EMBODYING THE INVENTION

### First Embodiment

Next, a first embodiment of a piezoelectric film sensor relating to the present invention will be described with reference to FIGS. 1-4.

The piezoelectric film sensor relating to this embodiment includes a substrate 1 having a folded portion 11, a signal electrode 2 and a ground electrode 3 formed on a face of the substrate 1, a piezoelectric film 5 formed of polyvinylidene fluoride (PVDF), and a bonding layer 6 for bonding the substrate 1 as being folded.

The piezoelectric film 5 generates an electric charge by the piezoelectric effect. In operation, when an external force is applied to the piezoelectric film 5 to deform this film 5, an electric charge generated in this deformed piezoelectric film 5 can be obtained as an electric signal.

FIG. 1 are developments in a plane view showing the electrode pattern formed on the substrate 1 of the piezoelectric film sensor relating to this embodiment. FIG. 1 (a) shows a face (front surface) on one side of the substrate 1 and FIG. 1 (b) shows the face (back surface) on the other side of the substrate 1. As shown in FIG. 1, the substrate 1, as being folded at its folded portion 11, is sectioned into two areas (in this specification, these areas will be referred to as a “first substrate portion” and a “second substrate portion”, respectively). On the front face of the first substrate portion 1a, the signal electrode 2 is provided and on the front face of the second substrate portion 1b, the ground electrode 3 is provided. Hence, these electrodes 2, 3 are provided on the same face (side) of the substrate 1. Further, on the back face of the first substrate portion 1a opposite to the face having the signal electrode 2 formed thereon, a second ground electrode 4 is formed. These electrodes are formed by using a known technique such as the electrode printing technique, the etching technique, etc.

In the above, the ground electrode 3 is formed over the entire face of the second substrate portion 1b and formed to extend beyond the folded portion 11 to the first substrate portion 1a.

As shown in FIG. 2, the substrate 1 is folded in such a manner that its face having the signal electrode 2 and the ground electrode 3 formed thereon is located on the inner side at the folded portion 11. With this folding, these electrodes are placed in opposition to each other, and between these opposed two electrodes, the piezoelectric film 5 formed of polyvinylidene fluoride (PVDF) is inserted. Then, the signal electrode 2 and the piezoelectric film 5, and the ground electrode 3 and the piezoelectric film 5 are bonded respectively to each other by the bonding layer 6 interposed therebetween. FIG. 3 shows the section of a detecting portion 9 of the piezoelectric film sensor thus obtained.

The piezoelectric film 5 is inserted to the area where the signal electrode 2 formed in the first substrate portion 1a and the ground electrode 3 formed in the second substrate portion 1b are overlapped with each other. In this embodiment, the inserted piezoelectric film 5 has a size corresponding to the area constituting the detecting portion 9 of the signal electrode 2. The material forming the piezoelectric film 5 can be other than PVDF. For instance, an electret material using polypropylene as a planar polymer material, can be used.

The bonding layer 6 is formed on the entirety of the substrate 1. That is, the bonding layer 6 bonds the first substrate portion 1a and the second substrate portion 1b over the entire areas thereof. The material forming this bonding layer 6 is not particularly limited, but this can be a bonding agent or an adhesive agent of the reaction type, solution type, hot-melt type, etc. However, as the bonding layer 6 is to be disposed between electrodes, for maintaining the sensitivity as the piezoelectric film sensor, it is preferred that a bonding agent having a high dielectric constant be selected. Further, for the similar purpose, it is preferred that the bonding layer 6 be formed thin.

Incidentally, in order to restrict the amount of PVDF to be used for the sake of cost reduction, it is possible to employ an arrangement of the piezoelectric film 5 being partially inserted between the signal electrode 2 and the ground electrode 3 overlapped with each other. In his case, the area where the piezoelectric film 5 is present should be smaller than the mutual opposing area between the ground electrode 3 and the signal electrode 2 and the bonding layer 6 should be configured according to the size of the substrate 1. As a result, the bonding layer 6 will function to prevent short circuit between the two electrodes in the area where the piezoelectric film 5 is not present.

The bonding layer 6 can be an “adhesive agent with a substrate” which corresponds to the substrate 1.

The second ground electrode 4 functions as a shield electrode. Namely, this prevents introduction of noise from the outside to the signal electrode 2, whereby the sensitivity as the piezoelectric film sensor is improved. However, in the case of application where not so high sensitivity is required, the second ground electrode 4 is not absolutely needed.

Incidentally, FIG. 3 shows an exemplary construction wherein protective films 8 are provided on the outer sides (the outer side of the second ground electrode 4 in the case of the first substrate portion 1a) of the folded substrate 1 via fixing agent 7. In this example, there is disclosed an arrangement wherein the protective film 8 is provided on each one of the upper and lower faces of the folded substrate 1. Instead, however, there may be provided a single folded protective film 8. The protective film 8 is not particularly limited as long as it is an insulating film. However, a resin film of polyethylene terephthalate (PET), polyethylene naphthalate (PEN) can be suitably used because of their high mechanical strength. In particular, if the protective film 8 of a same material type as the substrate 1 is used, even when a heating treatment is effected in affixing these together, inconvenience such as occurrence of warp can be avoided advantageously because of the common heat expansion ratio. Further, the fixing agent 7 can be a same bonding agent forming the bonding layer 6. But, the agent 7 can be different from the latter, also.

The protective film 8 is provided for protecting the substrate 1 against external mechanical stress applied from the outside. So, it is preferred that this film 8 be provided, but it is not an essential requirement.

As shown in FIG. 1 and FIG. 2, in the first substrate portion 1a, terminals 10 are formed. The ground electrode 3 extends through the inner side of the folded portion 11 of the substrate to be conductive with the first substrate portion 1a and extends up to the terminal 10. In this way, as the terminals of the signal electrode 2 and the ground electrode 3 are provided in a concentrated manner in the first substrate portion 1a, a positioning error is permissible at the time of the assembly during the folding operation for folding the substrate 1 such that its face formed with the signal electrode 2 and the ground electrode 3 is on the inner side. That is to say, the above arrangement eliminates the need of position-aligning operation between the terminals So, the assembly process can be simplified.

In this embodiment, as shown in FIG. 4, the ground electrode 3 is rendered conductive also with the second ground electrode 4 via the lateral face of the substrate 1, and the terminal of this second ground electrode 4 too is provided in the first substrate portion 1a.

Incidentally, the piezoelectric film 5 is not inserted to the portion other than the detecting portion 9. Therefore, the other portion does not have any sensitivity, so that noise generation therefrom can be effectively prevented.

The piezoelectric sensor described above can be provided in a face to contact a human, such as a seat of a vehicle, a seat of a movie theater or any other theater or a bed, so that the sensor can be suitably used in a system for obtaining various kinds of information of the human.

### Second Embodiment

Next, a second embodiment of the piezoelectric film sensor relating to the present invention will be described with reference to FIG. 5.

The piezoelectric film sensor relating to this embodiment, has a substantially same construction as the piezoelectric film sensor according to the first embodiment, but is distinguished therefrom in that the terminals 10 are provided at the folded portion 11 of the substrate 10.

FIG. 5 is a development in the plane view showing the electrode pattern formed on the substrate 1 of the piezoelectric film sensor according to this embodiment. In this embodiment, an angular hook-shape cutout 13 is formed from the center of the folded portion 11 toward the second substrate portion 1b. The signal electrode 2 extends beyond the folded portion 11 to the inside of the area delimited by the cutout 13. On the other hand, the ground electrode 3 is formed in the entire area of the second substrate portion 1b other than the area separated by the cutout 13 and the terminal ends of the inside of the area delimited by the cutout 13 and the ground electrode 3 is extended slightly from the folded portion 11 to the side of the first substrate portion 1a so as to interconnect these areas to form together an integrated electrode. In this way, in the area delimited by the cutout 13, the terminals of the signal electrode 2 and the ground electrode 3 are provided in a concentrated manner. In this case, when the substrate 1 is folded, the signal electrode 2 and the ground electrode 3 become exposed to be connected to an unillustrated connector.

With use of the above-described construction, the terminals 10 of the piezoelectric film sensor are provided in concentration at the folded portion 11. Hence, the length of an electrode to be extended from a different area to the terminal provided in the folded portion 11 can be short. Accordingly, the formation of electrodes can be carried out in an efficient manner.

Further, with the above-described construction, if e.g. a connector is connected to the terminals 10, this terminal connector fixes the folded portion 11 of the substrate 1, thus functioning as a “clamp” for restricting a force in the direction tending to exfoliate or separate the folded substrate 1. With this, further simplification of the assembly process and further improvement of the reliability of the piezoelectric film sensor are made possible.

For further effectively preventing resilient displacement, it is possible to provide e.g. a cutout at the folded portion 11 to reduce the exfoliation force or to fuse-fix the folded portion 11 per se.

### Third Embodiment

Next, a third embodiment of the piezoelectric film sensor relating to the present invention will be described with reference to FIG. 6.

The piezoelectric film sensor relating to this embodiment, has a substantially same construction as the piezoelectric film sensor according to the first embodiment, but is distinguished therefrom in that the substrate 1 includes two folded portions 11, 12.

FIG. 6 is a development in a plane view showing electrode pattern formed on the substrate 1 of the piezoelectric film sensor according to the present embodiment. In this embodiment, the substrate 11, as being folded at the folded portions 11, 12, is sectioned into three areas (in this specification, these areas will be referred to as the “first substrate portion”, the “second substrate portion” and the “third substrate portion”, respectively). Here, the first substrate portion 1a and the second substrate portion 1b are sectioned from each other by the first folded portion 11, and the second substrate portion 1b and the third substrate portion 1c are sectioned from each other by the second folded portion 12. On the front face of the first substrate portion 1a, the signal electrode 2 is provided. On the front face of the second substrate portion 1b, the ground electrode 3 is provided and on the front face of the third substrate portion 1c, the second ground electrode 4 is provided, thus these electrodes are provided on the same single face of the substrate 1.

The substrate 1, like the other embodiments, is folded so as to place its face formed with the signal electrode 2 and the ground electrode 3 on the inner side. By the folding, these electrodes become overlapped with each other, and between the signal electrode 2 and the ground electrode 3, the piezoelectric film 5 formed of polyvinylidene fluoride (PVDF) is inserted. The substrate 1 is further folded at the second folded portion 12 so as to cause the ground electrode 3 and the second ground electrode 4 to sandwich the signal electrode 2 therebetween. As a result, the substrate 1 is folded at the two portions, so that the signal electrode 2 is overlapped with the ground electrode 2 and the second ground electrode 3 as being sandwiched therebetween. The second ground electrode 4 functions as shield electrode, and the folded substrate 1 is fixed by the bonding layer 6.

In this way, by providing the two folded portions 11, 12 in the substrate 1, it is possible to complete electrode formation on the one face thereof only. With this, it becomes possible to manufacture a piezoelectric film sensor with even further reduction in its manufacture cost, even easier assembly and high sensitivity.

### Other Embodiments

(1) In the respective foregoing embodiments, there have been described the examples wherein the signal electrode 2 and the ground electrode 3 are formed on a same face of the substrate 1 and the substrate 1 is folded so as to place its face formed with these electrodes on the inner side. However, as long as the piezoelectric film 5 can be inserted between the signal electrode 2 formed in the first substrate portion 1a and the ground electrode 3 formed in the second substrate portion 1b when the substrate 1 is folded, the substrate 1 may be folded so as to place the electrodes formed on the same face on the outer side. Further alternatively, the substrate 1 may be folded, with the two electrodes being formed on the different faces respectively.

(2) In the third embodiment described above, there was described the example in which the substrate 1 is folded with the signal electrode 2, the ground electrode 3 and the second ground electrode 4 being formed on the same one face of the substrate 1. However, as long as the piezoelectric film 5 can be inserted between the signal electrode 2 formed in the first substrate portion 1a and the ground electrode 3 formed in the second substrate portion 1b when the substrate 1 is folded, these electrodes need not be formed on a same one face.

(3) In the first and third embodiments described above, there were shown the example wherein the ground electrode 3 is formed on the entire surface of the second substrate portion 1b and extends beyond the folded portion 11 to reach the first substrate portion 1a, thus providing the terminals in the concentrated manner in the first substrate portion 1a. However, the means for providing the terminals in a concentrated manner in the first substrate portion 1a is not limited thereto. For instance, it is also possible to employ such means for establishing conduction therebetween via a lateral face of the substrate 1 or via other member or forming in advance opposed electrodes in the first substrate portion 1a and the second substrate portion 1b and then establishing conduction therebetween not via the bonding layer 6, but through direct contact therebetween.

(4) In the first and third embodiments described above, there was shown the example wherein the ground electrode 3 is formed to extend to the first substrate portion 1a, thus concentrating the terminals in the first substrate portion 1a. However, it is not absolutely needed to provide them in concentration in the first substrate portion 1a. For instance, it is possible to employ an alternative construction wherein the signal electrode 2 is formed to extend to the second substrate portion 1b, thus concentrating the terminals in this second substrate portion 1b.

(5) In the respective foregoing embodiments, there were shown the examples wherein the terminals 10 are formed, with concentrating the terminals of the signal electrode 2 and the ground electrode 3 at positions in close vicinity with each other. However, the positions of the respective terminals may be away from each other as long as they are provided on either one of the first and second portions of the substrate 1.

(6) In the respective foregoing embodiments, there were shown the examples in which the substrate 1 is folded at one position or two positions. However, as long as the piezoelectric film 5 can be inserted between the signal electrode 2 formed in the first substrate portion 1a and the ground electrode 3 formed in the second substrate portion 1b when the substrate 1 is folded, these electrodes need not be formed on a same one face, the substrate 1 can be folded at more than three portions.

### INDUSTRIAL APPLICABILITY

The present invention may suitably be used in e.g. a pressure sensor for determining presence/absence of a human, an animal, an object, etc.

1. A piezoelectric film sensor comprising:
a substrate having a signal electrode and a ground electrode formed on the surface thereof, the substrate being folded to cause the signal electrode and the ground electrode to be overlapped with each other in a plane view;
a piezoelectric film inserted between the signal electrode and the ground electrode formed on the substrate; and
a bonding layer for bonding the folded substrate thereby to affix the signal electrode, the ground electrode and the piezoelectric film together.

2. The piezoelectric film sensor according to clam 1, wherein terminals of both the signal electrode and the ground electrode are provided in a concentrated manner in at least one of a plurality of areas of the substrate sectioned from each other by the folding.

3. The piezoelectric film sensor according to claim 1, wherein the signal electrode and the ground electrode are formed on a same face of the substrate.

4. The piezoelectric film sensor according to claim 1, wherein on the back side of the face having the signal electrode formed thereon, a second ground electrode is formed.

5. The piezoelectric sensor according to claim 1, wherein the substrate is folded at least two portions thereof to cause the signal electrode to be sandwiched between the ground electrode in the plane view.

6. The piezoelectric film sensor according to claim 1, wherein terminals of the signal electrode and the ground electrode are provided in a concentrated manner at the folded portion of the substrate.

7. The piezoelectric film sensor according to claim 1, wherein the substrate includes a first substrate portion and a second substrate portion that are sectioned from each other by the folding of this substrate; and
the signal electrode is provided in the first substrate portion and the ground electrode is provided in the second substrate portion.

8. The piezoelectric film sensor according to claim 1, wherein the substrate is folded at least at two portions so as to cause the signal electrode to be sandwiched by a ground electrode in the plane view;
the substrate includes a first substrate portion, a second substrate portion and a third substrate portion that are sectioned from each other by folding of the substrate;
the first substrate portion and the second substrate portion are sectioned from each other by a first folded portion and the second substrate portion and the third substrate portion are sectioned from each other by a second folded portion; and
the signal electrode is provided in the first substrate portion, the ground electrode is provided in the second substrate portion and the second ground electrode is provided in the third substrate portion.

9. The piezoelectric film sensor according to claim 6, wherein in the periphery of the two terminals of the signal electrode and the ground electrode provided in the concentrated manner, a cutout is formed, so that with the folding of the substrate, the two terminals are exposed to the outside.
